(19) United States
(12) Patent Application Publication
(10) Pub. No.: US 2013/0017374 A1
(43) Pub. Date: Jan. 17, 2013

(54) CARBON NANOTUBES NANOCOMPOSITES FOR MICROFABRICATION APPLICATIONS

(71) Applicants: Marijana Mionic, Lausanne (CH); Arnaud Magrez, Mieussy (FR); László Forró, Ecublens (CH); Sébastien Maurice Jiguet, Chavannes-pres-Renens (CH); Moshe Patrick Judelewicz, Pully (CH); Thierry Stora, Thoiry (FR)

(72) Inventors: Marijana Mionic, Lausanne (CH); Arnaud Magrez, Mieussy (FR); László Forró, Ecublens (CH); Sébastien Maurice Jiguet, Chavannes-pres-Renens (CH); Moshe Patrick Judelewicz, Pully (CH); Thierry Stora, Thoiry (FR)

(73) Assignee: ECOLE POLYTECHNIQUE FEDERALE DE LAUSANNE, Lausanne (CH)

(21) Appl. No.: 13/510,200

(22) PCT Filed: Nov. 18, 2010
(86) PCT No.: PCT/IB10/55276

§ 371 Date: Oct. 1, 2012

(30) Foreign Application Priority Data
Nov. 18, 2009 (EP) 09176358.1

(51) Int. Cl. C08L 63/00; C08K 5/1539; G03F 7/20; C08L 63/04; B05D 5/00; B05D 3/12; B05D 3/06; B32B 33/00; B32B 27/38; G03F 7/004; C08K 7/06; B82Y 30/00

(52) U.S. Cl. 428/195.1; 430/280.1; 522/71; 522/75; 522/31; 430/322; 430/296; 427/256; 427/240; 427/553; 427/552; 427/555; 977/742

(57) ABSTRACT

A composite epoxy resin consisting in a SU-8 epoxy resin, a solvent, with or without photoinitiator and carbon nanotubes in powder. When the resin is combined with the carbon nanotubes, the mechanical, thermal and electrical properties of the nanocomposite are enhanced. That offers a wide range of composites which can be used with different micro-fabrication techniques, such as: lamination, spin-coating, spraying and screening for assembly, interconnect and packaging applications.

### FTFLD OF THE INVENTION

The present invention relates to the field of carbon nanotubes (CNTs), and more particularly, but not by way of limitation, to a CNTs/polymer composite, in which properties of the polymer are modified and improved by the addition of CNTs.

The present invention also relates to a method for producing the CNTs/polymer nanocomposite and, more particularly, to a nanocomposite material for microfabrication applications based on octafunctional epoxidized novolac resins such as SU-8.

### BACKGROUND OF THE INVENTION AND RELATED PRIOR ART

“Nanotechnology” refers to nanometer-scale phenomenon atypical for the macroscopic objects, as well as nanometer-scale manufacturing processes, materials and devices. Nanotechnology has been in the last decades in the focus not only of the scientific research, but also of the industry, because nanotechnologies have produced materials with extraordinary properties which open broad potential applications.

CNTs are often viewed as the hallmark of this new generation of nanomaterials resulting from nanotechnology. Since their discovery in 1991 (see, e.g. S. Iijima, Nature 56, 354 (1991)), CNTs have been at the forefront of the nanomaterials research. This special attention arises from their outstanding electrical, mechanical, thermal and optical properties in combination with their extraordinary chemical stability, low density and very high tuneable aspect ratio (see, e.g. R. Saito, G. Dresselhaus, and M. S. Dresselhaus, Physical Properties of Carbon Nanotubes (World Scientific, Singapore, 1998)). Therefore, they are considered as the most suitable candidate as reinforcing fibres in composites especially polymers (see, e.g. P. J. F. Harris, Carbon Nanotubes and Related Structures: New Materials for the Twenty-First Century (Cambridge University Press, Cambridge, 1999)), in order to improve their properties (especially electrical, thermal and mechanical). This is the reason why recently composite materials using CNTs have attracted much attention. Such composite materials are expected to have improved mechanical strength and to become electrically conductive owing to the incorporation of CNTs in the insulating polymer matrix.

However, since CNTs mutually have a strong aggregating property, it is considered to be very difficult to homogeneously disperse them in the majority of mediums. CNTs are insoluble in any organic solvents. Inter-tube interactions within the CNTs are dominated by van der Waals interactions of high cohesive energy (see, e.g. Girifalco L. A. et al.: Physical Review B (PRB) 62, 19 (2000) 13104). Therefore, CNTs have a tendency to aggregate due to extremely high surface energy, which is for example 123 mJ/m² at 37° C. for multi walled CNTs (see, e.g. Zhang X. et al.: J. Mater. Sci. 42 (2007) 7069, Papirer E. et al.: Carbon 37 (1999) 1265).

Strong aggregation of the CNTs results in their low solubility and low dispersability. This is heavily affecting their mechanical and electronic properties, and present serious problem for CNTs based composite applications. Several methods have been tried to overcome this obstacle and to reduce the short-range attraction between CNTs. The methods include chemical modifications of CNTs' surface by functionalization (see, e.g. Chen J. et al: Science 282 (1998) 95; Boul P. et al.: Chem Phys. Lett. 310 (1999) 367) or surfactant adsorption (see, e.g. Vigolo B. et al.: Science 290 (2000) 1331; Wang J. et al.: J. Am. Chem. Soc. 125 (2003) 2408; Moore V. C. et. al.: NanoLetters 3, (2003) 1379). These methods involve several disadvantages. It was, for example, shown that covalent modification often leads to impairing of mechanical and electrical properties of CNTs (see, e.g. Garg A. and Sinnott S. B.: Chem. Phys. Lett. 295 (1998) 273), and to a change in the electronic structure (see, e.g. Chen J. et. al.: Science 282 (1998) 95). The other methods based on surfactants are either restricted to low concentrations of CNTs (see, e.g. Vigolo B. et al.: Science 290 (2000) 1331) or they can induce additional problems due to the chemical interactions in complex chemical systems, like for example photosensitive composites.

On the other hand, photosensitive materials are materials which undergo a physical and/or chemical change upon exposure to certain energy, for example to light of certain wavelength. A good example of a photosensitive material is the SU-8 photoresist, manufactured by the company named Gersteltec. SU-8 photoresist is a negative tone, epoxy functional type, near-UV photoresist based on EPON SU-8 epoxy resin (from Shell Chemical) that was originally developed, and patented by IBM (see for example EP 0 222 187 B1; U.S. Pat. Nos. 4,237,216 and 4,882,245). Upon exposure to near UV light, cationic ring-opening polymerisation occurs, SU-8 cross-links and forms highly stable bonds providing extraordinary chemical stability of SU-8 (even exposed to fluoric acid). This process allows structuring of SU-8 into highly complex patterns which can be two or three dimensional, on a substrate or free standing.

A further unique advantage of SU-8 photoresist is that it can be used for thin to ultra-thick layers deposition and structuring. For example, single layers of SU-8 have been shown to be as thick as 2 mm and structures with an aspect ratio greater than 50 have been demonstrated. All these properties have naturally led to significant interest in SU-8 for use in microfabrication applications. However, SU-8 is an electrically insulating material with a very low thermal conductivity.

One of the features that are often necessary for many applications is electrical conductivity. In order to open possibilities for even bigger variety of applications required by emerging technology, it would be desirable to be able to produce SU-8 composite materials which are electrically conductive, biocompatible, with enhanced thermal conductivity, mechanical properties, flexibility, adhesion towards bigger variety of substrates, with tuneable transparency, but with a preserved ability to process and pattern SU-8 photoresist.

There have been many attempts to achieve this. For example, to realize electrical conductivity there have been made composites of SU-8 with: silver nanoparticles (see, e.g. Jiguet S. et al.: Advance Functional Materials 15 (2005) 1511) or carbon based materials (see, e.g. Chiamori H. C. et al.: Microelectronic Journal (2007) doi:10.1016/j.mejo.2007.05.012). In the first case electrical percolation is achieved with 6 vol. % and samples are not transparent. In the second case the best result reported is a resistance around 35 MΩm for 5 wt % of CNTs and decrease of mechanical properties.

For example, to improve mechanical properties there have been made composites of SU-8 with: silica nanoparticles (see, e.g. Jiguet S. et al.: Microelectronic engineering 83 (2006) 1966) or CNTs (see, Xu X. et al.: Applied Physics Letters 81 (2002) 2833). In both cases the increase of Young's modulus, as this is a main mechanical property of material, was about 20% and electrical conductivity was not achieved. In the second case chloroform was used as SU-8 solvent but using of chloroform for the composite preparation is unsuitable for an industrial use of this composite due to the toxicity of chloroform. Furthermore, in the second case, content of CNTs could not be higher than 0.1 wt % due to the high viscosity of the mixture and that is the second major obstacle for composite applications.

Despite the significant energy that has been focused into making CNTs/SU-8 composite, several problems remain unsolved. The first problem is dispersion of CNTs in GBL, standard solvent of SU-8. There have been reported achievement of almost 40% of dispersed CNTs in GBL were individual CNTs at a concentration of 6×10⁻⁴ mg/ml (see, e.g. Bergin S. D. et al.: Nanotechnology 18 (2007) 455705), that is few order of magnitude lower than required for conductive composite preparation. There has been attempts to obtain good dispersion of CNTs is GBL and SU-8 by using surfactant, but even stable dispersion have been reported (see, e.g. Zhang N. et al.: Smart Materials and Structures 12 (2003) 260), using of such composite for patterning and processing was not achieved.

### SUMMARY OF INVENTION

It is therefore an aim of the present invention to improve the known methods of preparing polymer composites.

More specifically, it is an object of this invention to provide a method for preparing CNTs/SU-8 nanocomposite, which is electrically conductive, biocompatible, with enhanced thermal conductivity, mechanical properties, flexibility, adhesion towards bigger variety of substrates, with tuneable transparency, but with a preserved ability to process and pattern the CNTs/SU-8 photosensitive nanocomposite material.

This and other objects of the present invention are reached by the products and methods defined in the appended claims.

### BRIEF DESCRIPTION OF THE DRAWINGS

The present invention will be better understood from the following description, examples and from the figures in which:

FIG. 1 shows SU-8 oligomer unit;

FIG. 2 shows transmission electron micrographs of: a) CVD CNTs as produced and b) entangled and coiled after purification;

FIG. 3 shows an illustration of a method for producing CNTs/SU-8 photosensitive nanocomposite material;

FIG. 4 shows a block diagram of a method based on UV-lithography for processing of CNTs/SU-8 composites;

FIG. 5 shows an illustration of a composite layer containing interlocked non-regular network of physically connected CNTs and chemically cross-linked SU-8;

FIG. 6 shows an illustration of percolating CNTs network inside of SU-8 matrix.

FIG. 7 illustrates a setup for a four-point measurement of electrical resistance;

FIG. 8 illustrates a graph of electrical resistance of a composite as a function of CNTs concentration;

FIG. 9 illustrates the thermal conductivity of a composite as a function of CNTs concentration;

FIG. 10 illustrates the Young's modulus of a CNTs/SU-8 composite as a function of CNTs weight concentration;

FIG. 11 illustrates the hardness of a CNTs/SU-8 composite as a function of CNTs weight concentration;

FIG. 12 illustrates TEM micrographs of composite samples;

FIG. 13 illustrates a HR SEM micrograph of fracture surface of a CNTs/SU-8 composite sample;

FIG. 14 illustrates TGA and DSC curves of pure SU-8 photoresist and CNTs/SU-8 photosensitive nanocomposite material;

FIG. 15 illustrates a wafer with microstructures made of SU-8/CNTs composite prepared by photolithography;

FIG. 16 illustrates example of microstructures made of SU-8/CNTs composite prepared by photolithography;

FIG. 17 illustrates a transparent microstructure of SU-8/CNTs composite prepared by photolithography;

FIG. 18 shows transparent CNTs/SU-8 layers on glass slide (a, b) or free standing (c);

FIG. 19 illustrates examples of microstructures based on SU-8/CNTs composite prepared by screen printing.

### DETAILED DESCRIPTION OF THE INVENTION

This invention concerns a new nanocomposite layer based on epoxy resin with functionalized or non-functionalized carbon nanotubes (CNTs) that can be polymerized either thermally or photo chemically for microsystem and semiconductor applications (packaging, nanopackaging, insulator and dielectrics, interconnect layers, display devices, neural devices (electrode), coating and substrates for solar applications).

This invention relates in particular the changing of the physico-chemical-thermal and mechanical properties of EPON SU-8 by mixing it with CNTs. The formulation is a dispersion of CNTs in SU-8 matrix and suitable solvent of the SU-8 epoxy resin (acetone, ester, acetate, etc . . . ).

The specific composition of the CNTs/SU-8 composite is selected to optimize the desired properties. It will of course be understood that by modifying the concentration of each components of the formulation, this will affect the final properties of the composite.

A decrease in any of the elements below a critical percentage or an excess of any of the elements above a critical percentage will result in properties, which are unacceptable for the use of the composite photoresist or not, in microfabrication and for applications related to the new properties brought by the CNTs, as electrical conductivity and enhancement of mechanical and thermal properties. For example, below a minimal concentration of photoiniator, the photosensitive composite will not polymerize enough for photo-patterning applications, and it results no structures or structures with deformations and low resolution which are not usable. For example, above a maximal concentration in CNTs, the composite photoresist will not photo-polymerize because of the optical and chemical phenomena induced by the carbon nanotubes and/or surfactant which avoid the activation of the photoinitiator. In that case, the non-photosensitive composite is interesting since it can be thermally polymerized.

The polymerization of the composite is influenced by several phenomena induced by the CNTs: a problem of dispersion of the CNTs in the SU-8 resist due to chemical incompatibilities between both components will affect the optical properties of the photosensitive composite, as well as the dimensions, the shape and the concentration of the CNTs in the formulation, which results in a photochemical problem and a non polymerization of the photosensitive composite.

The shape, dimensions and concentration of the CNTs control the characteristics (resolution, sidewall verticality, deformations) of the composite patterned structures required for microsystems.

Moreover, that also induces electrical conductivity to the non conductive SU-8 matrix (10⁻¹⁴ S·cm⁻¹) which also evolves with the concentration, the dispersion, the shape, the nature and the dimensions of the carbon nanotubes, electrically conductive (10⁴⁻⁶ S·cm⁻¹).

The composite based on carbon nanotubes dispersed in the SU-8 resin shows a wide range of mechanical, thermal and electrical properties which are comprised between that of the matrix and that of the carbon nanotubes. Thus a broad map of composites can be formulated with specific characteristics (mechanical, electrical, optical, and thermal) and optimized for specific applications, such as anti-static film, shielding screen, electrical paths, conductive and flexible film, etc . . . .

The present invention deals in particular with the development of new photosensitive and/or thermosensitive composite based on the dispersion of CNTs in the SU-8 resin, with electrical conductivity, lower internal stress, increased flexibility and adhesion towards bigger variety of substrates, increased mechanical and thermal properties, which can be used for microfabrication technologies or others for which these composites can be suitable.

The goal of the invention is achieved through the features reported in examples 1 to 8.

The new photosensitive nanocomposite material consists in a SU-8 epoxy resin, a solvent, surfactants and carbon nanotubes (CNTs) dispersed in the mixture. In case of a photosensitive or non-photosensitive composite, a photoinitiator is added to the previous mix. The properties of the composite and the composite structures depend on the quality of the CNTs dispersion.

It is possible to add one or more further optional additives such as an adhesion promoter, or a coating leveling agent, or a flame retardant, or pigments or dies to modify the optical properties of the material, in the composite material. Other additives may be envisaged depending on the properties one wishes to reach.

The preparation methods described below were found to perform very well for microsystem applications.

### Step 1: CNTs Synthesis

CNTs can be synthesized by few fabrication processes: (Laser ablation, Arc Discharge process, high-pressure carbon monoxide (HIPCO) process, Chemical Vapour Deposition (CVD), Hot Filament CVD, Plasma Enhanced CVD,). For example: Carbon Nanotubes are produced by CVD of acetylene over Fe₂Co particles supported by CaCO₃. Growth temperature is 640° C. Acetylene, Nitrogen flux are respectively 10 L/h and 70 L/h. CNTs are subsequently purified with hydrochloric acid. 4 grams of raw CNTs are dispersed in 1 L of 1.5 M of HCl. See article M Mionic et al Physica Status Solidi B 245, 1915-1918 (2008). CNTs are subsequently functionalized by dispersing them in nitric acid (HNO₃) and sulfuric acid (H₂SO₄). In standard procedures, 3.4 g of purified CNTs are treated in 200 ml of water and 50 ml of HNO₃ and 150 ml of H₂SO₄ for 1 to 24 h.

### Step 2: CNTs Drying

On the end of step 1 CNTs are in aqueous solution. The following step, a drying process, has to be performed. For example, this can be done by freeze drying of the aqueous solution containing CNTs which includes freezing by dipping solution in liquid nitrogen and drying under the vacuum conditions.

### Step 3: Control of CNTs

The CNTs length can be controlled by mechanical cutting. For instance, cutting is performed, for example by planetary ball milling, in the following conditions: rotation of the jar 100 to 600 rpm, 50 gr of ZrO₂ balls (diameter is 3 mm-15 mm) and 1-10 gr of CNTs are dispersed in 100 ml of distilled water. The grinding can be performed as well in organic solvents which are suitable to solubilise SU8 like for example GBL. in this case, CNTs drying after purification could be performed by known techniques less demanding than the one mentioned in step 2.

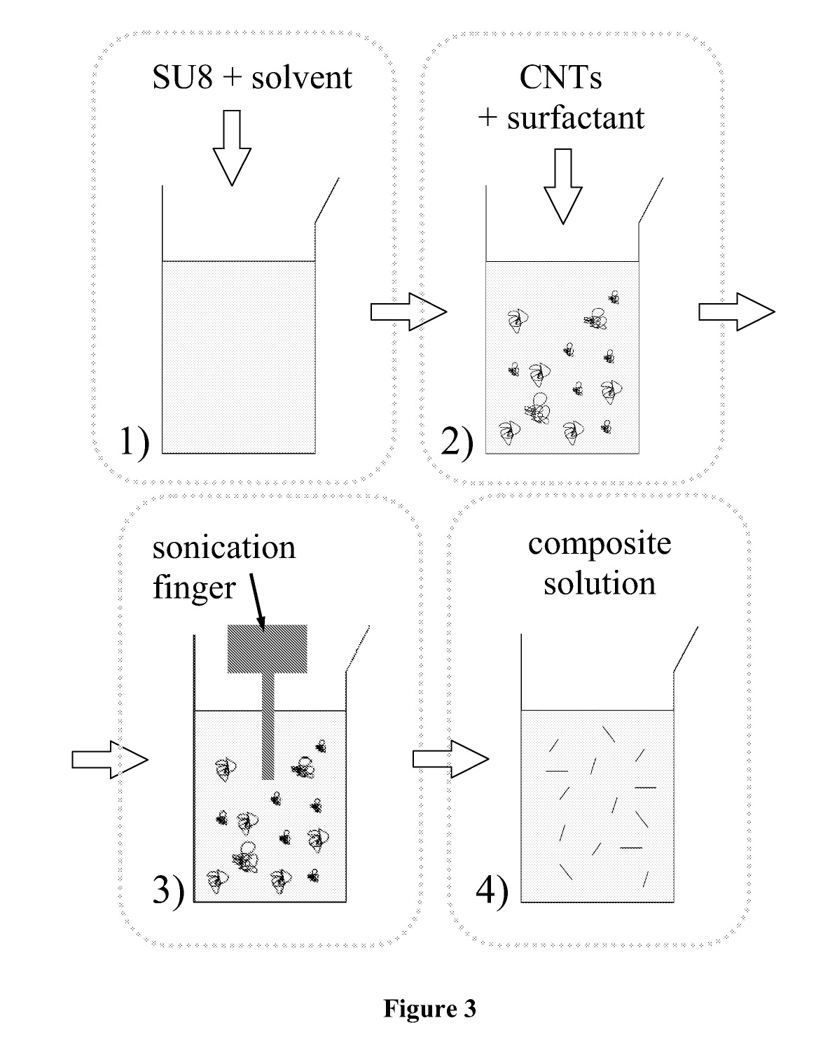

### Step 4: Nanocomposite Material Preparation (FIG. 3)

Negative tone epoxy resin SU-8 (EPONTM Resin SU-8) is dissolved into different solvents, moderately polar, such as (non-limiting examples): Acetone, Anisole, Benzene, Benzyl alcohol, Cyclopentanone, Gamma butyrolactone, Ethyl methyl Ketone, Methylene chloride, Phenol, Propylen glycol methyl ether acetate, Ethyl acetate, Propylene carbonate, Toluene, 1-Methyl-2-pyrolidone, Dimethylsulfoxide, Chloroform and Isopropanol. For the last four solvents, solution becomes murky after 48 h, otherwise the others provides a stable solution.

All good solvents for SU-8 resin are used as a starting solution for mixing dissolved SU-8 with CNTs. We studied the influence of CNTs surface functionality on their dispersitivity in all this solutions. Therefore we used CNTs just purified (nonfunctionalised) and CNTs functionalisation by oxygen containing groups like COOH, OH etc.

We used different methods to disperse CNTs in SU-8 solutions. Methods are long lasting stirring, adding surfactant, sonication in the sonication bath and with the sonication finger for different durations and different intensities and combination of mentioned 4 methods. In one of the methods to achieve good and stable dispersion of CNTs in SU-8 matrix we used different surfactants (as non-limiting examples): SDS, ODA, Span 60, Span 65, Span 80, Span 85, Tween 80, Disperbyk-101, Disperbyk-102, Disperbyk-103, Disperbyk-104, Disperbyk-105, Disperbyk-106, Disperbyk-107, Disperbyk-108, Disperbyk-112, Disperbyk-115, Disperbyk-116, Disperbyk-130, Disperbyk-145, Disperbyk-160, Disperbyk-161, Disperbyk-164, Disperbyk-166, Disperbyk-167, Disperbyk-168, Disperbyk-169, Disperbyk-170, Disperbyk-171, Disperbyk-183, Disperbyk-185, Disperbyk-187, Disperbyk-2000, Disperbyk-2001, Disperbyk-2008, Disperbyk-2009, Disperbyk-2010, Disperbyk-2012, Disperbyk-2015, Disperbyk-2025, Disperbyk-2095, Disperbyk-2150, Disperbyk-2155, Disperbyk-2163, BYK-012, BYK-016, BYK-020, BYK-024, BYK-028, BYK-032, BYK-038, BYK-044, BYK-067, BYK-302, BYK-9076 and BYK-9077.

Disperbyk-106 is salt of a polymer with acidic groups without solvent with typical properties of having 74 mg KOH/g amine value and 132 mg KOH/g acid value, while Disperbyk-2070 is acrylate copolymer with pigment affinic groups with typical properties of having 20 mg KOH/g amine value and 40 mg KOH/g acid value.

In SU-8 formulations containing from 0.5 wt % to 85 wt % of solid SU-8 resin in solvent (listed above) we add surfactants (listed above) in weight which corresponds to values from 0.1 wt % to 1000 wt % of surfactant in the weight of CNTs. Upon performed from one to ten days vigorous stirring to obtain good dispersion of surfactant in the SU-8 solution, we add CNTs in weight which corresponds to from 0.01 wt % to 10 wt % of CNTs in the weight of SU-8. Furthermore we used this method of dispersing CNTs in SU-8 solution in combination with other methods listed (like stirring lasting from 10 minutes to 10 days, sonication in the sonication bath lasting from 10 minutes to 24 h, sonication with the sonication finger from 1 to 20 times 1 to 60 minutes intervals with or without cycles on the 10 to 80% of power of sonication fingers with 100 or 200 W).

### Step 5: Photo/Thermo Sensitivity

The SU-8/CNTs photosensitive nanocomposite materials can be polymerized either thermally (example 5.) or photo chemically (examples band 8) by adding a highly efficient cationic photoinitator. A thermoinitiator can also be used, but polymerisation will be limited to a thermal activation.

In order to perform photo or thermal crosslinking process (polymerization) of the photosensitive nanocomposite material, we add a cationic photoinitiator (PI) from the family of sulfonium salt. The best result was obtained when photoinitiator Tris-[4-(4-acetyl-phenylsulfanye-phenyl]-sulfonium-tris (trifluoromethanesulfonyl) methide was used. The weight percent of photoinitiator with respect to weight of SU-8 used in this case was from 0.01 to 20 wt % with respect to the weight of SU-8. Photoinitiators in powder form or photoinitiators in liquid form may be used.

All other cationic photo or thermal initiators may also be used, mainly in their powder form (but not limited to this form).

### Step 6: Microfabrication of Nanocomposite Parts

Depending on the nanocomposite material viscosity (from liquid to paste), different techniques to make a layer can be applied:
For low to medium viscosity, spray-coating, spin-coating and inkjet-printing are recommended
For medium to high viscosity, spin-coating, doctor blade and screen-printing are more suitable.

To pattern the nanocomposite layer, several microfabrication processes can be used: UV-lithography, electron-beam, ion-beam, laser beam, ink jetprinting, microstereolithography (and stereolithography), screen-printing.

Moulding and casting are also recommended to obtain structures, even if 3D and complex shapes are not so easy to reach at a micro-scale range.

For each of these techniques/processes, photo or thermo activation of the polymerization can be applied, and sometimes both at the same time (e.g. laser beam structuration). Examples 5 & 6 described two of them.

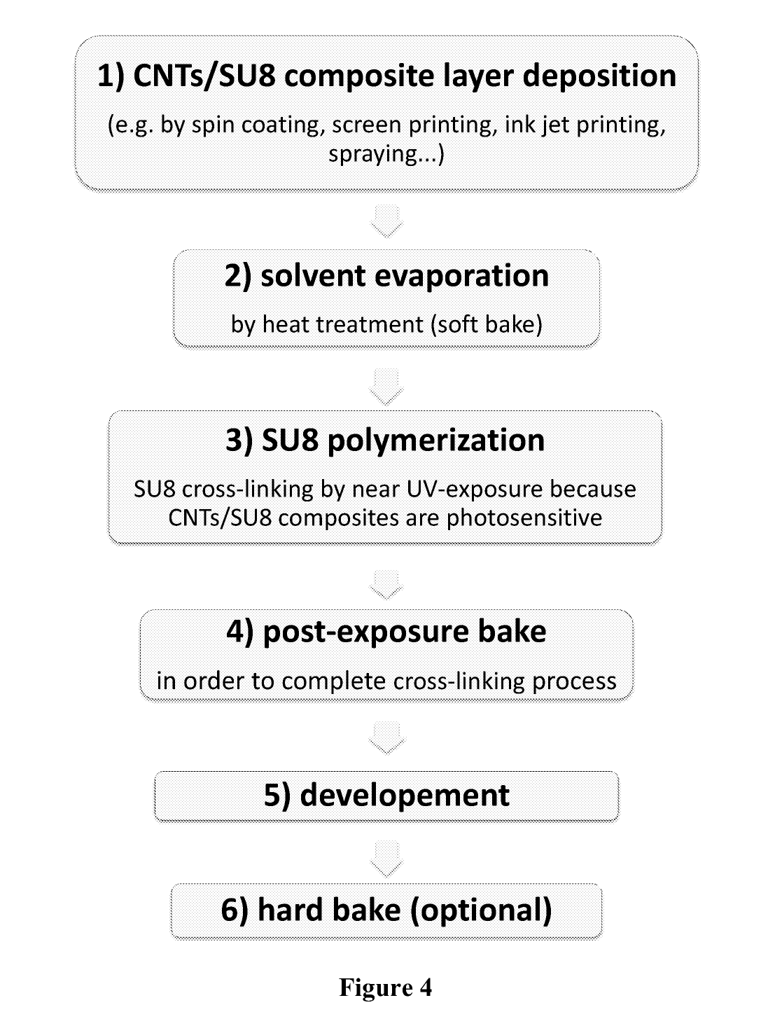

### Step 6bis: UV-Photolithography (FIG. 4)

Standard photolithography process had to be modified in the following way: 1) spin coating plateau time has to be reduced (typically at 5 sec) and acceleration/deceleration time has to be increased(at about 200 rpm/s) with respect to a standard spin coating procedure step 2) Soft baking step has to be longer since solvent evaporation is slowed down by presence of CNTs, but the temperature value should remain the same as in the standard procedure. 3) UV exposition time depends on the composite layer thickness as in standard process. 4) Post exposure baking have to be done at higher temperature than as mentioned in the standard process, instead of 95° C. temperature of 120° C. should be used. The time on the plateau and the rate of temperature acceleration/deceleration should remain the same as in a standard process procedure. 5) Development has to be longer and depending on the thickness of composite layer required time for dipping wafer with composite in PGMEA is from 15 minutes to 1 h. Time required for dipping wafer with composite in IPA is few minutes but is not a critical value. 6) Hard baking can be performed, but it's not an essential step of the process.

Turning now to the figures:

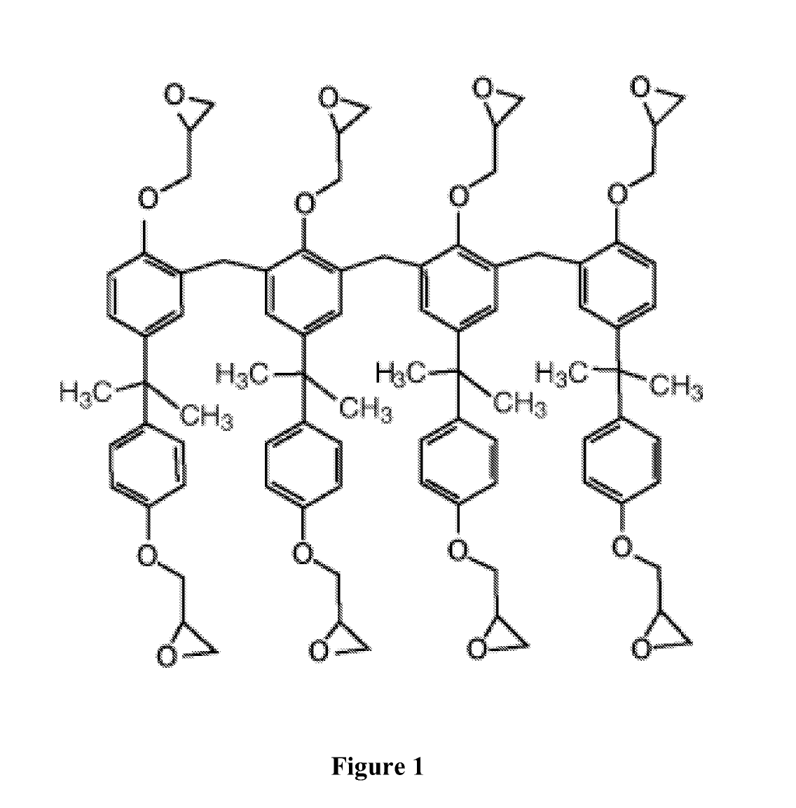

FIG. 1 shows SU-8 oligomer unit as mentioned above.

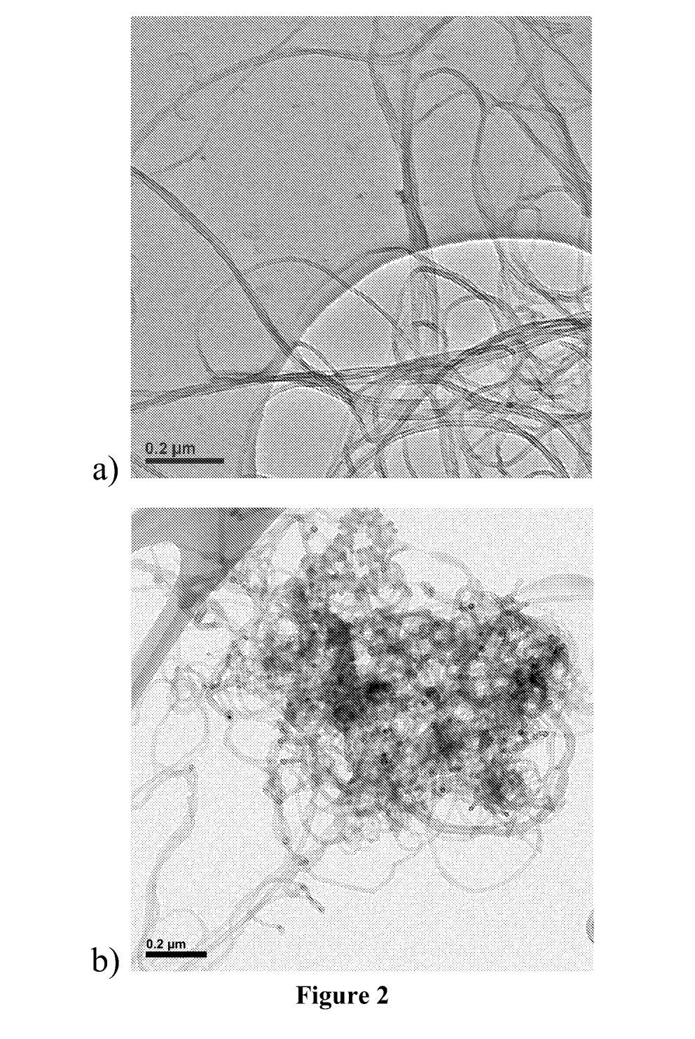

FIG. 2 illustrates transmission electron micrographs (TEM) of:

a) CVD CNTs as produced and

b) Entangled and coiled after purification.

FIG. 3 shows an illustration of a method for producing CNTs/SU-8 composites. Typically, as also described above in step 4, firstly SU-8 is provided and a solvent added (step 1 in FIG. 3). Then, CNTs and a surfactant are added (step 2 in FIG. 3). To disperse the CNTs in the SU-8 solution one uses, for example, a sonication finger (step 3 in FIG. 3) and finally, the composite solution is obtained (step 4 in FIG. 3). Of course, this is only an example and other equivalent methods and steps may be used (see step 4 above in the description).

FIG. 4 shows a block diagram of a method for processing of CNTs/SU-8 composites to obtain an end product (for example parts as described above in step 6 above). As illustrated, the first step is a layer deposition of the SU-8/CNTs composite. Several methods are suitable, such as spin coating, screen printing, ink jet printing, spraying and other equivalent methods.

Then, the next step is evaporation of the solvent used in the preparation of the composition (see process illustrated in FIG. 3 and corresponding description). This can be done, for example, by heat treatment, such as a soft baking.

The next step is the polymerisation of the SU-8 structures. This step can be carried out by UV exposure for example since the composite is photosensitive and post exposure baking (see also step 5 above).

The next step is the development with which non-polymerized part of composite is removed, while polymerized structures remain. Process can be followed by hard baking which can further improve material's properties (like e.g. adhesion).

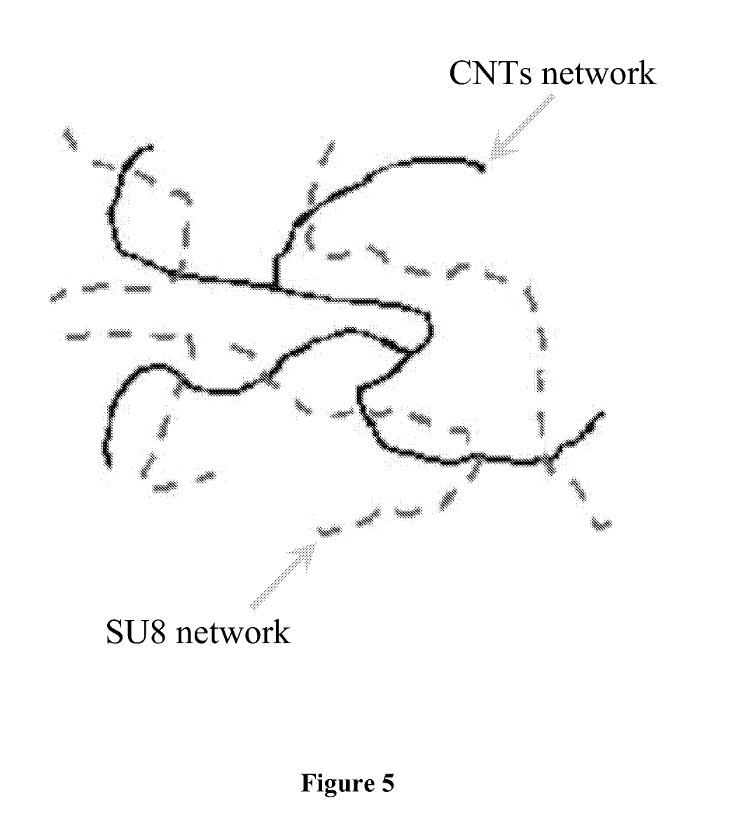

FIG. 5 is an illustration of a composite layer containing interlocked non-regular network of physically connected CNTs and chemically cross-linked SU-8.

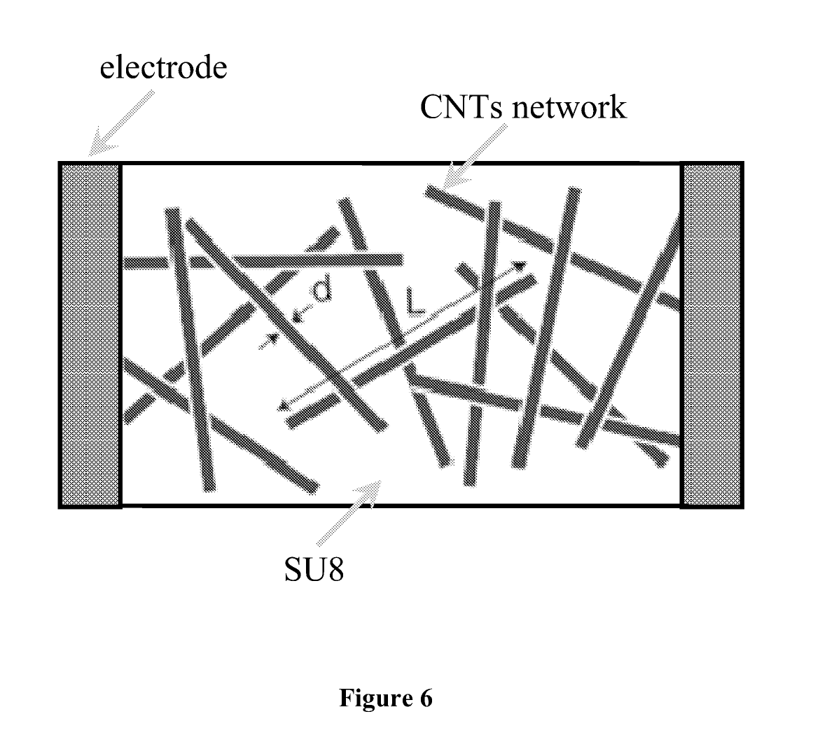

FIG. 6 is an illustration of percolating CNT network inside an SU-8 matrix.

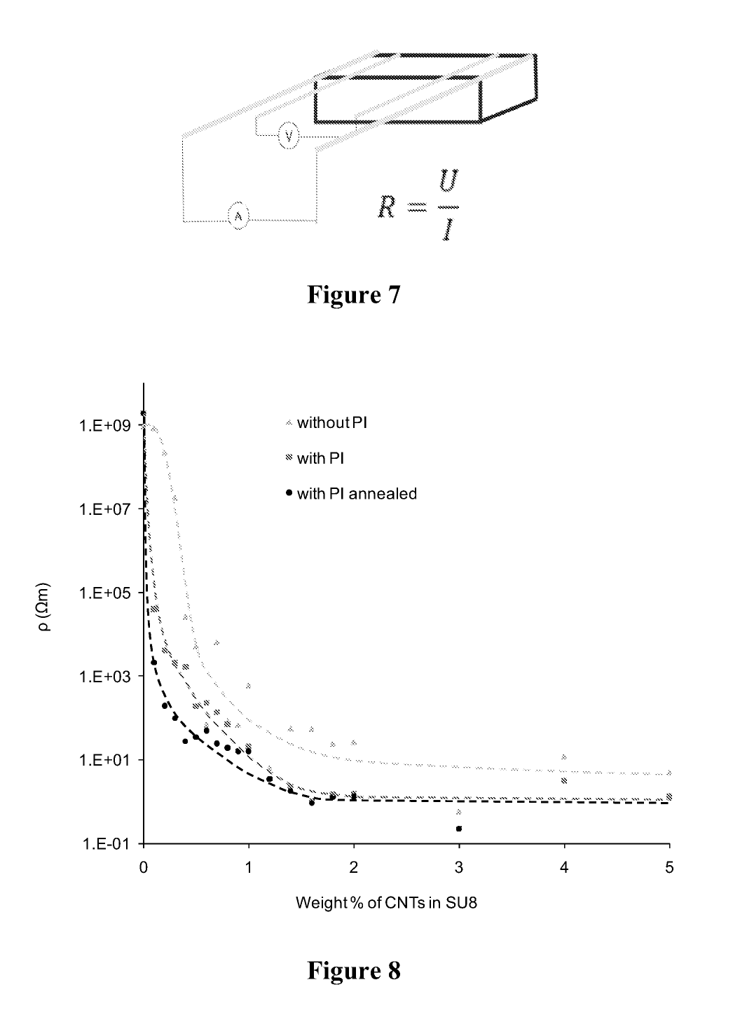

In FIG. 7, a setup for a four-point measurement of electrical resistance is represented and in FIG. 8 a graph of electrical resistance of the composites as a function of CNT concentration is represented.

More specifically, obtained composite samples were used to measure the electrical properties of composites CNTs-SU-8.

FIG. 8 shows results of 4-point measurement of the photo/thermo sensitive composites prepared with adding surfactant, photoinitiator and with CNTs as a function of CNTs' concentration. Composites contain from 0.04 to 5 wt % of CNTs with respect to the weight of SU-8. One can see that a composite sample containing only 0.04 wt % of CNTs in SU-8 is already electrically conductive. In other words, by adding only 0.04 wt % of CNTs electrical resistance decreases by 5 orders of magnitude and by adding 1.2 wt % of CNTs electrical resistance decreases by 9 orders of magnitude as compared to pure SU-8 material.

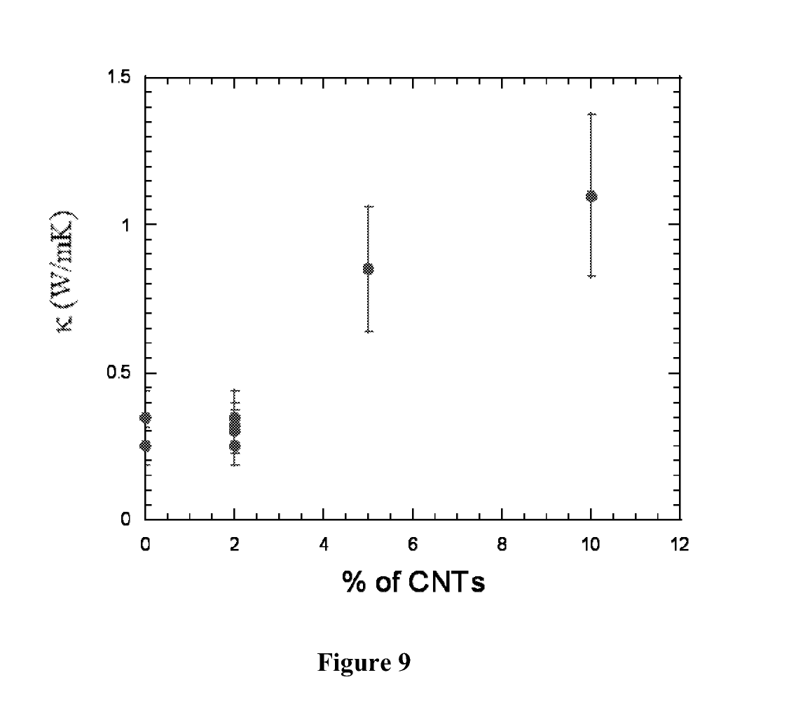

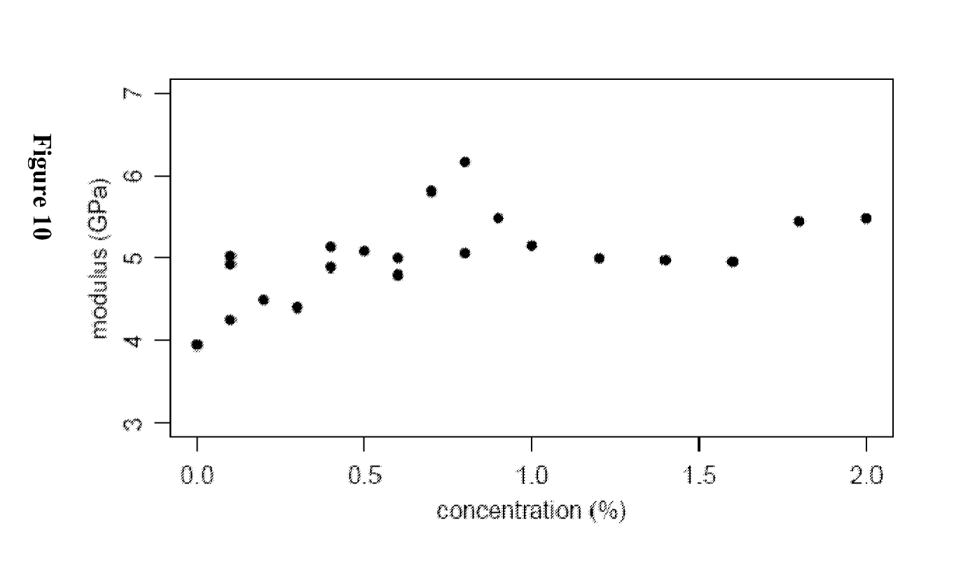

FIG. 9 illustrates the thermal conductivity of a composite as a function of CNTs concentration. Obtained composite samples were used to measure the thermal properties of composites CNTs-SU-8. FIG. 9 shows results of thermal conductivity measurement of the photo/thermo sensitive composites prepared with adding surfactant, photoinitiator and with CNTs without functionalization as a function of CNTs' concentration. By making composite with randomly oriented CNTs thermal conductivity can be increased up to 4 times. The thermal conductivity at room temperature grew from 0.3 W/mK at zero concentration to 1.1 W/mK at 10 wt % concentration of CNTs with respect to the weight of SU-8.

FIG. 10 illustrates the Young's modulus of CNTs/SU-8 composite as a function of CNTs weight concentration and

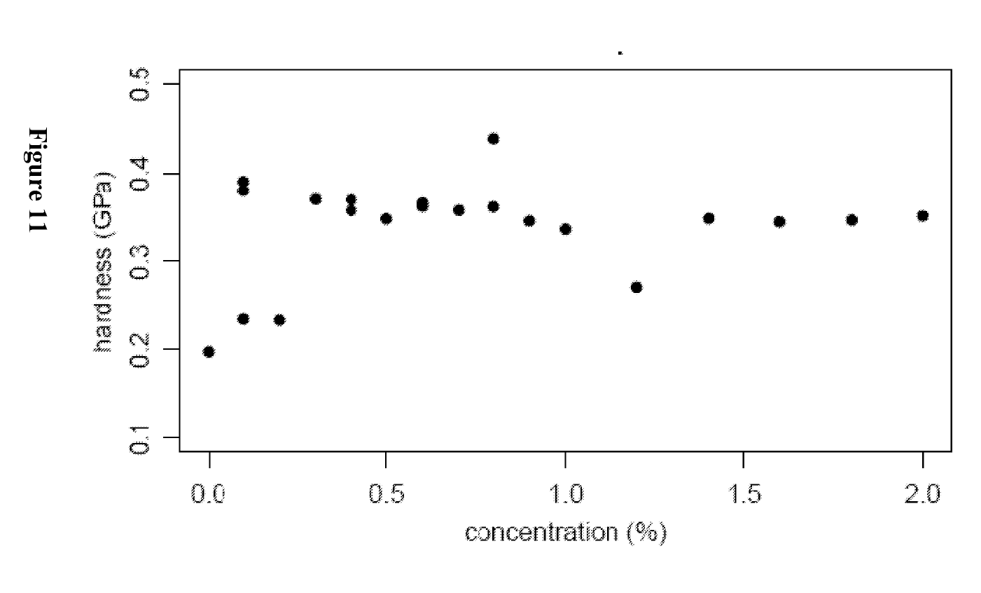

FIG. 11 illustrates the hardness of a CNTs/SU-8 composite as a function of CNTs weight concentration. We measured mechanical properties (Young's modulus and hardness) of CNTs/SU-8 composite layers by nano-indentation. Hardness increases from 197 MPa to 438 MPa with only 0.8 wt % of CNTs with respect to the weight of SU-8 and Young's modulus from 3.95 GPa to 6.17 GPa for the same composite (with 0.8 wt %).

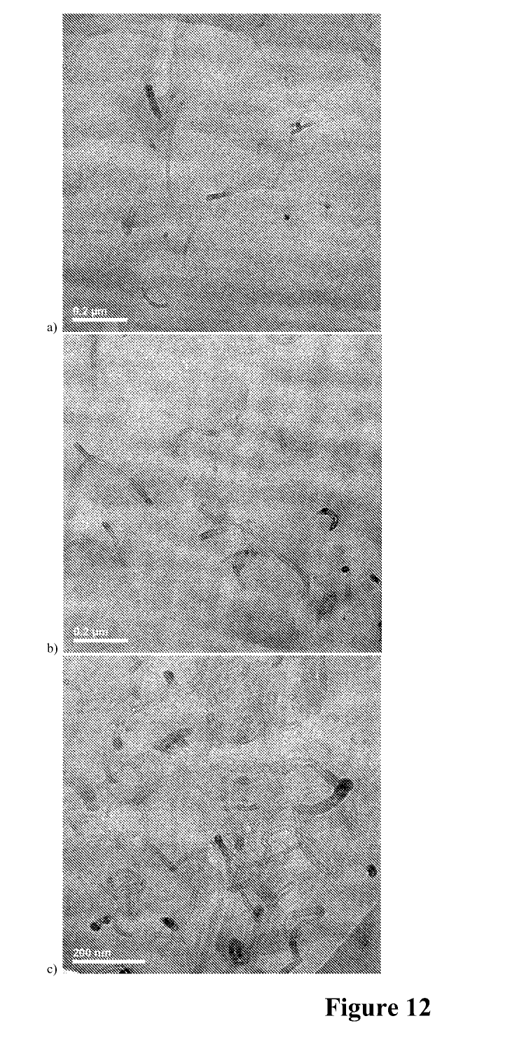

FIG. 12 illustrates TEM micrographs of composite samples showing good dispersion of CNTs in SU-8 matrix for the CNTs weight concentrations of: a) 0.2; b) 0.5 and c) 1.4.

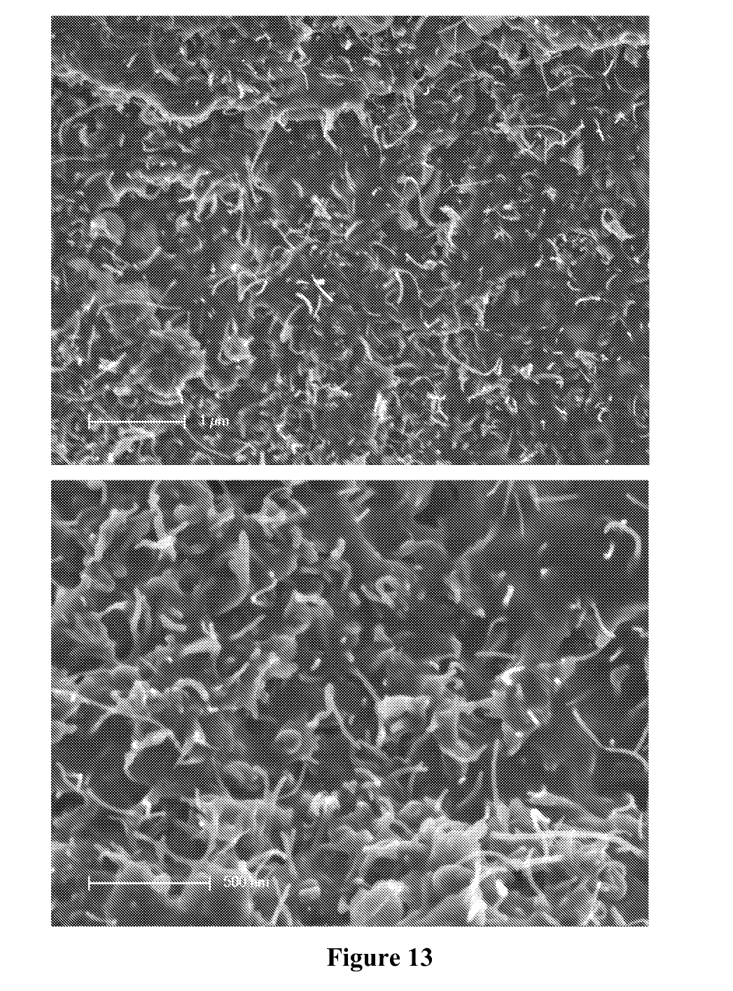

FIG. 13 illustrates a HR SEM micrograph of fracture surface of a CNTs/SU-8 composite sample containing 3 wt % of CNTs where one can see that good CNTs' dispersion is preserved even for high CNTs loads.

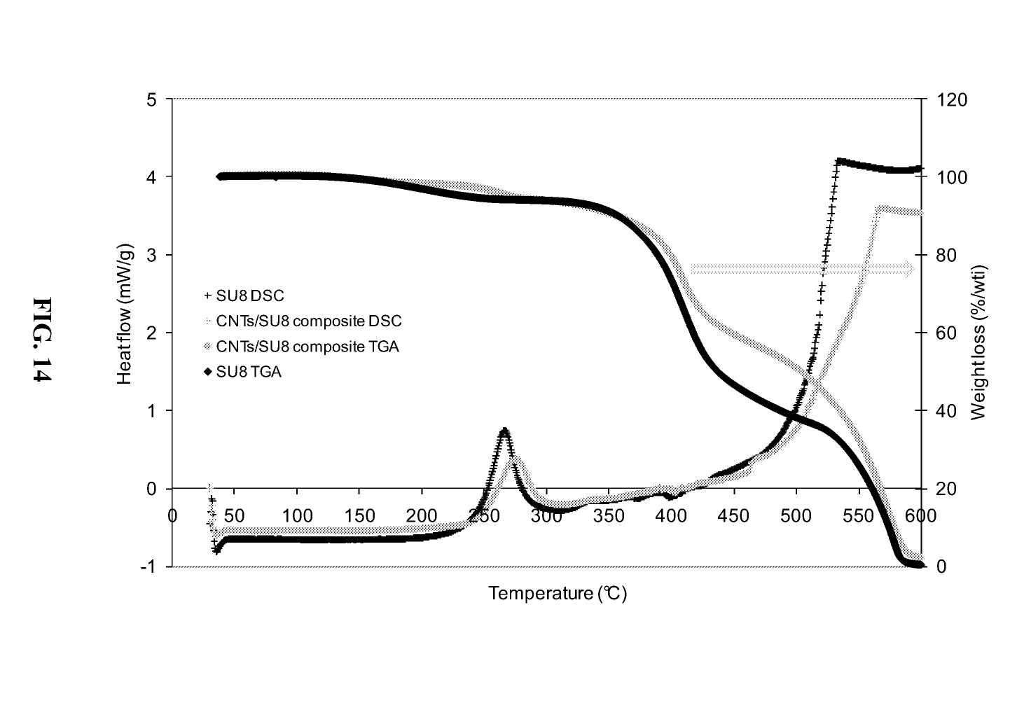

FIG. 14 illustrates TGA (thermogravimetric analysis) and DSC (differential scanning calorimetry) curves of SU-8 and CNTs/SU-8 composite. The DSC curves confirm thermal activation of photoinitiator.

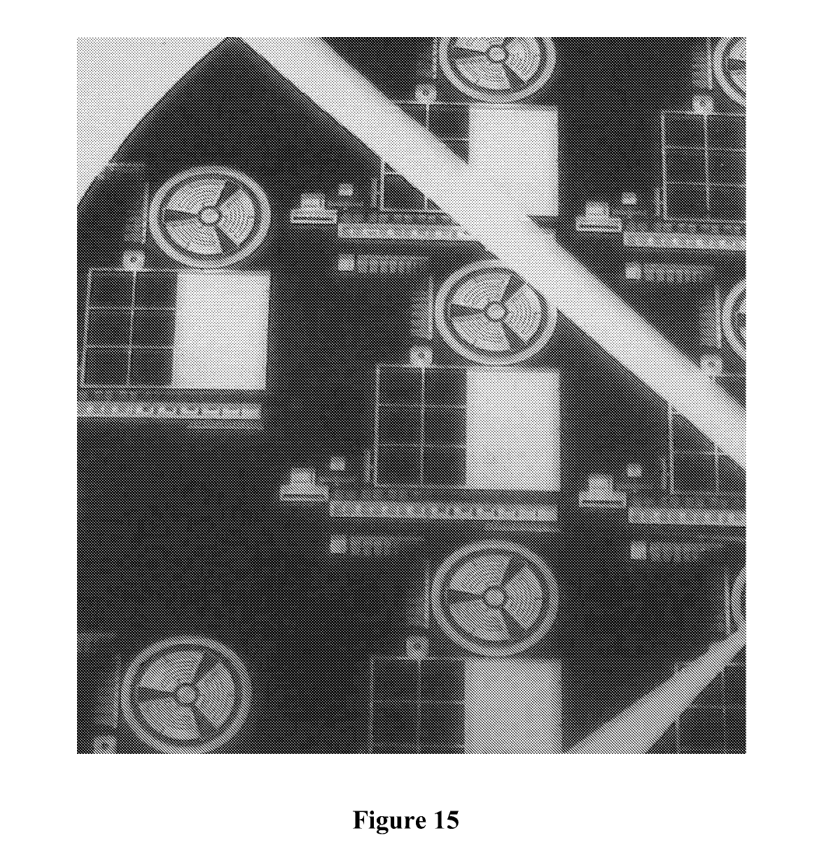

FIG. 15 illustrates a wafer with microstructures made of SU-8/CNTs composite and made by UV photolithography.

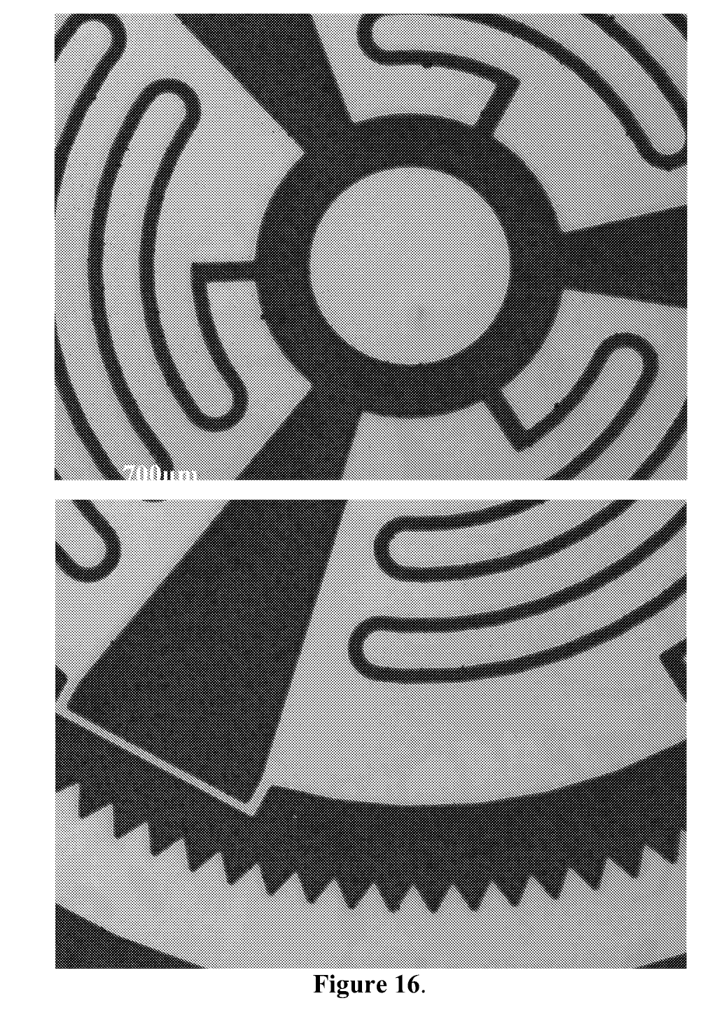

FIG. 16 is an image of microstructures made of SU-8/CNTs composite prepared by UV photolithography.

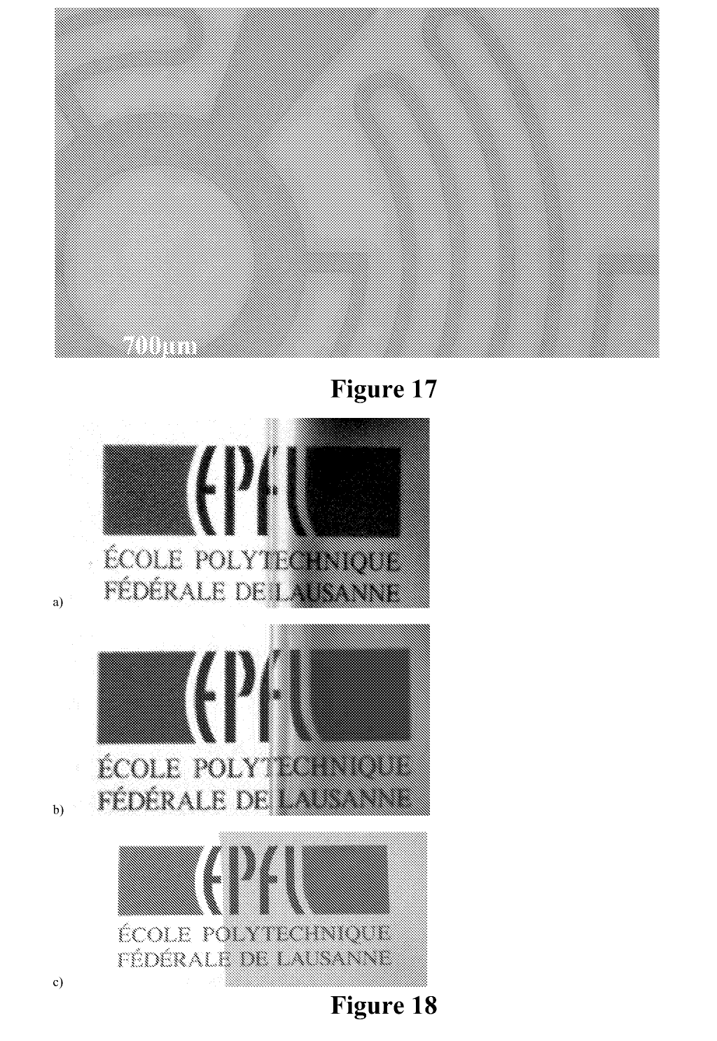

FIG. 17 is an image of transparent microstructures of CNTs/SU-8 composite layer prepared by UV photolithography process.

FIG. 18 shows transparent CNTs/SU-8 layers on glass slide (a, b) or free standing (c) composite layer obtained by lifting of layer upon UV photolithography process.

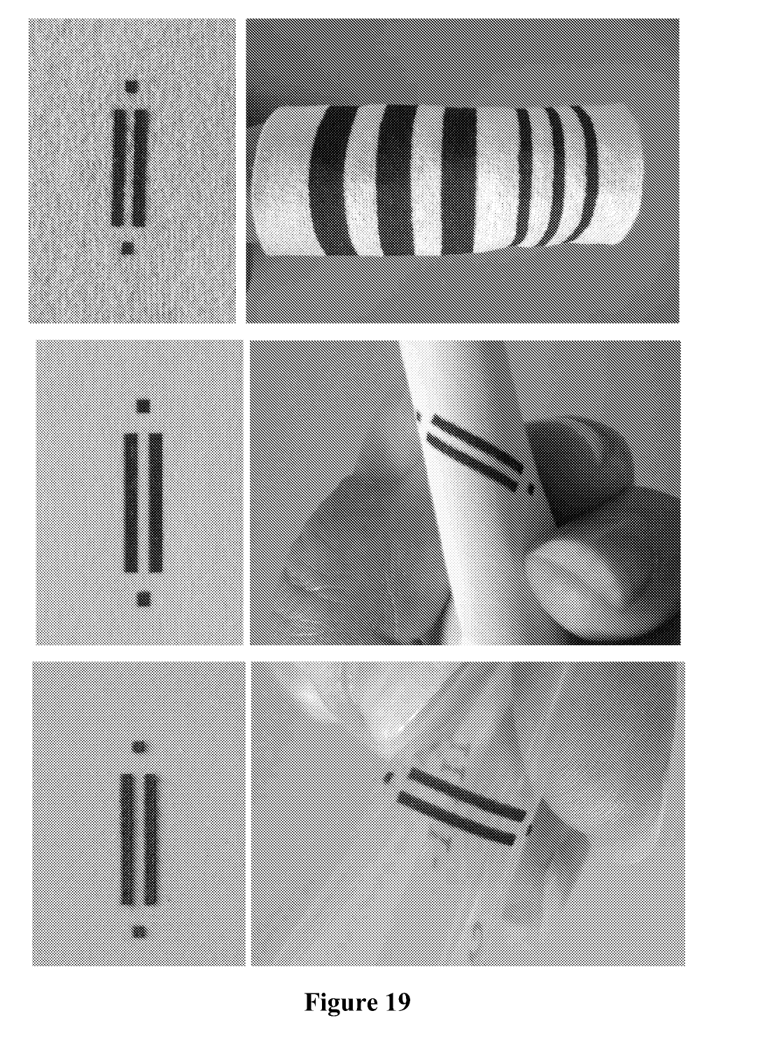

FIG. 19 illustrates examples of microstructures based on SU-8/CNTs composite prepared by screen printing. More specifically, they are images of microstructures based SU-8-CNTs composite prepared by screen printing on: textile (first row), paper (second row) and on plastic foil (third row). One can see that CNTs/SU-8 composite layer is still flexible even for thick layers. One can see as well that adhesion is excellent and for atypical substrates (like textile, paper and plastic foil). Adhesion and flexibility of composite layers is preserved even in case of layer deposited on flexible substrates, like in this FIG. 19.

### EXAMPLES OF COMPOSITES

### Example 1

0.5 gr of —COOH functionalized CNTs powder was added in 10 gr of methylethyl ketone (MEK) and sonicated in the sonication bath over 6 h. Epon™ Resin SU-8 in solid foam was mechanically ground until a fine powder was obtained. Powder was sieved through colanders with 500, 300, and finally with 150 mm mesh. Obtained SU-8 powder was in small quantities added regularly under vigorous stirring until we add all 10 gr of SU-8 powder. Quantity of tube was fixed to 5 wt % in respect to SU-8.

### Example 2

In 19.23 gr of SU-8 formulation containing 65 wt % of solid SU-8 in GBL, which corresponds to 12.5 gr of pure SU-8, we add surfactant BYK-038 in weight which corresponds to values of 17.5 wt % of surfactant in the weight of CNTs. Upon performed 12 h vigorous stirring to obtain good dispersion of surfactant in the SU-8 solution we add 0.1 gr of nonfunctionalized CNTs what corresponds to 0.8 wt % of CNTs in the weight of SU-8.

Solution was sonicated in the 4 interval of 60 minutes on 10% of power by the sonication finger having power of 100 W.

### Example 3

In 31.25 gr of SU-8 formulation containing 40 wt % of solid SU-8 in GBL, which corresponds to 12.5 gr of pure SU-8, we add surfactant Disperbyk-2155 in weight which corresponds to values of 32.8 wt % of surfactant in the weight of CNTs. Upon performed 24 h vigorous stirring to obtain good dispersion of surfactant in the SU-8 solution we add 0.2 gr of CNTs what corresponds to 1.6 wt % of CNTs in the weight of SU-8. Solution was sonicated in the 10 interval of 15 minutes on 20% of power by the sonication finger having power of 200 W.

### Example 4

In solutions described in example 2 we add a cationic photoinitiator (triarylsulfonium salt family) in the quantities which correspond to 0.1 wt % to 50 wt % of PI in SU-8, to obtain final photo-sensitive composites. In the solution from example 4 we add 1.25 gr or PI, what corresponds to 10 wt % of PI in the weight of SU-8.

### Example 5

By heat treating composites from example 4 above 130° C. crosslinking of the SU-8 matrix occurs due to thermal activation of photoinitiator. This method of polymerization can be used for moulding and screen-printing.

### Example 6

The photopatterning of the photosensitive nanocomposite layer from example 4 can be made by UV-lithography process (Step 6bis) considering the i, g and h lines, at the same time or separately.

### Example 7

Direct structuring of the layer may be made by a screen-printing process (FIG. 19). CNTs/SU-8 composite was printed through the mask with holes in the shape of desired pattern. As a printing substrate we used standard 80 g/m2 copy paper. Structures were subsequently baked on 95° C. for 10 minutes in order to evaporate solvent and then baked as described in example 5 in order to thermally activate photoinitiator and to induce the crosslinking of SU-8.

### Example 8

Direct photopatterning can be applied to the photosensitive nanocomposite material. Solution of photo-sensitive composite was spincoated on quartz wafer on 500 rpm and baked on 95° C. for 15 minutes in order to evaporate solvent. Upon 2000 mJ/cm2 exposure to UV light as described in example 6, the exposed layer is baked 15 minutes on 95° C. and developed to reveal the photopatterned structures by dipping wafer 5 minutes in the PGMEA and 1 minute in isopropanol.

By contrast with the prior art examples given above to realize electrical conductivity with silver nanoparticles or carbon based materials, electrical percolation is achieved with 0.04 wt % of CNTs and samples with tuneable transparency, adhesion to atypical substrates with preserved flexibility have been obtained. The best result reported is a resistance around 0.2 Ωm for 3 wt % CNTs and decrease of mechanical properties.

As illustrated, many used for this composite material may be foreseen with many different shapes as described above. In particular, it can be used in case where adhesion bonding is needed in addition to electrical properties (i.e. low resistivity). For example, it can be used in the fabrication of supercapacitors.

Of course, all the embodiments and examples given above are cited as non-limiting examples of the invention and should not be interpreted in a limited manner Other variants and equivalents are possible within the scope of the present invention.

1. A nanocomposite material comprising at least:
a. an epoxy resin
b. a solvent
c. carbon nanotubes (CNTs) in powder
d. a photoinitiator, such as a photosensitive agent.

2. A composite material as defined in claim 1, wherein the carbon nanotubes are functionalized.

3. A composite material as defined in claim 1, wherein the carbon nanotubes are non-functionalized and the material comprises in addition a surfactant.

4. A composite material as defined in claim 1, wherein it comprises one or more further optional additives such as an adhesion promoter, or a coating leveling agent, or a flame retardant, or pigments or dies to modify the optical properties of the material.

5. A composite material as defined in claim 1, wherein the carbon nanotubes (CNTs) are in powder form and are dispersed in the dissolved epoxy resin.

6. A composite material as defined in claim 1, comprising 0.01 wt % to 10 wt % of CNTs in the weight of epoxy resin.

7. A composite material as defined in claim 1, wherein the epoxy resin is the EPON™ resin SU-8.

8. A composite material as defined in claim 1, wherein the solvent is the gamma butyrolactone or other solvents of the epoxy resin.

9. A composite material as defined claim 3, comprising from 0.1 wt % to 1000 wt % of surfactant in the weight of CNTs.

10. A photosensitive composite material as defined in claim 1, wherein the cationic photosensitive agent or photoinitiator is based on a sulfonium salt containing either a hexafluorophosphate group or a hexafluoroantimonate group, or on a tri[4-(4-acethyl-phenylsulfanyl)-phenyl]-sulfonium-tris(trifluoromethanesulfonyl) methide, and generally on a highly efficient cationic photoinitiator.

11. A method for preparing a composite material according to claim 1, comprising at least the steps of:
providing an epoxy resin,
adding at least a solvent
adding functionalized or non-functionalized carbon nanotubes (CNTs),
optionally adding a surfactant if the carbon nanotubes are non-functionalized;
dispersing the CNTs in the epoxy resin solution.

12. A method for fabricating a product with a composite material as defined in claim 1, comprising at least the steps of
forming a layer of said composite material;
patterning said layer of material.

13. The method of claim 12, wherein the layer of material is formed by spray-coating, or spin-coating, or inkjet printing, or doctor blade, or screen-printing.

14. The method of claim 12, wherein the patterning of the layer of material is made by UV lithography, electro-beam, ion-beam, laser beam, ink-jet printing, micro-stereolithography, or screen-printing.

15. A product comprising a composite material as defined in claim 1 and obtained by the method comprising at least the steps of
forming a layer of said composite material;
patterning said layer of material.
